(19) United States
(12) Patent Application Publication
(10) Pub. No.: US 2025/0083950 A1
(43) Pub. Date: Mar. 13, 2025

(54) SENSOR

(71) Applicant: KABUSHIKI KAISHA TOSHIBA, Tokyo (JP)

(72) Inventors: Hiroaki YAMAZAKI, Yokohama Kanagawa (JP); Yoshihiko KURUI, Chigasaki Kanagawa (JP)

(73) Assignee: KABUSHIKI KAISHA TOSHIBA, Tokyo (JP)

(21) Appl. No.: 18/760,470

(22) Filed: Jul. 1, 2024

(30) Foreign Application Priority Data
Sep. 12, 2023 (JP) 2023-147722

(51) Int. Cl. B81B 7/02; G01F 1/684; G01F 1/69

(52) U.S. Cl. CPC B81B 7/02; G01F 1/6845; G01F 1/69; B81B 2201/0292; B81B 2207/056

(57) ABSTRACT

According to one embodiment, a sensor includes a sensor portion that includes a first resistance element, a first opposing resistance element, a second resistance element, a second opposing resistance element, a third resistance element, a third opposing resistance element, a fourth resistance element, a fourth opposing resistance element, and a first conductive member. A direction from the first resistance element to the first opposing resistance element and a direction from the second resistance element to the second opposing resistance element are along a first direction. A second direction from at least a part of the first resistance element to the second resistance element crosses the first direction. A third direction from the third resistance element to the third opposing resistance element crosses a plane including the first and second directions. A direction from the fourth resistance element to the fourth opposing resistance element is along the third direction.

### CROSS-REFERENCE TO RELATED APPLICATIONS

This application is based upon and claims the benefit of priority from Japanese Patent Application No. 2023-147722, filed on Sep. 12, 2023; the entire contents of which are incorporated herein by reference.

### FIELD

Embodiments described herein relate generally to a sensor.

### BACKGROUND

For example, there are sensors using MEMS (Micro Electro Mechanical Systems) elements. It is desired to improve the characteristics of sensors.

### BRIEF DESCRIPTION OF THE DRAWINGS

FIGS. 1A and 1B are schematic cross-sectional views illustrating a sensor according to a first embodiment;

FIGS. 2A and 2B are schematic plan views illustrating the sensor according to the first embodiment;

FIG. 3 is a circuit diagram illustrating a part of the sensor according to the first embodiment;

FIGS. 4A and 4B are schematic cross-sectional views illustrating a sensor according to the first embodiment;

FIGS. 5A and 5B are schematic plan views illustrating the sensor according to the first embodiment;

FIGS. 6A and 6B are schematic cross-sectional views illustrating a sensor according to a second embodiment;

FIGS. 7A and 7B are schematic plan views illustrating the sensor according to the second embodiment;

FIGS. 8A and 8B are schematic cross-sectional views illustrating a sensor according to the second embodiment;

FIGS. 9A and 9B are schematic plan views illustrating the sensor according to the second embodiment;

FIGS. 10A and 10B are schematic plan views illustrating a sensor according to the second embodiment;

FIGS. 11A and 11B are schematic cross-sectional views illustrating a sensor according to the second embodiment;

FIGS. 12A and 12B are schematic plan views illustrating the sensor according to the second embodiment; and

FIG. 13 is a schematic cross-sectional view illustrating a sensor according to an embodiment.

### DETAILED DESCRIPTION

According to one embodiment, a sensor includes a sensor portion. The sensor portion includes a first resistance element, a first opposing resistance element, a second resistance element, a second opposing resistance element, a third resistance element, a third opposing resistance element, a fourth resistance element, a fourth opposing resistance element, and a first conductive member. A direction from the first resistance element to the first opposing resistance element is along a first direction. A second direction from at least a part of the first resistance element to the second resistance element crosses the first direction. A direction from the second resistance element to the second opposing resistance element is along the first direction. A direction from at least a part of the first opposing resistance element to the second opposing resistance element is along the second direction. A third direction from the third resistance element to the third opposing resistance element crosses a plane including the first direction and the second direction. A direction from at least a part of the third resistance element to the fourth resistance element is along the second direction. A direction from the fourth resistance element to the fourth opposing resistance element is along the third direction. A direction from at least a part of the third opposing resistance element to the fourth opposing resistance element is along the second direction. A position of the first conductive member in the first direction is between a position of the first resistance element in the first direction and a position of the first opposing resistance element in the first direction. A position of the first conductive member in the third direction is between a position of the third resistance element in the third direction and a position of the third opposing resistance element in the third direction.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

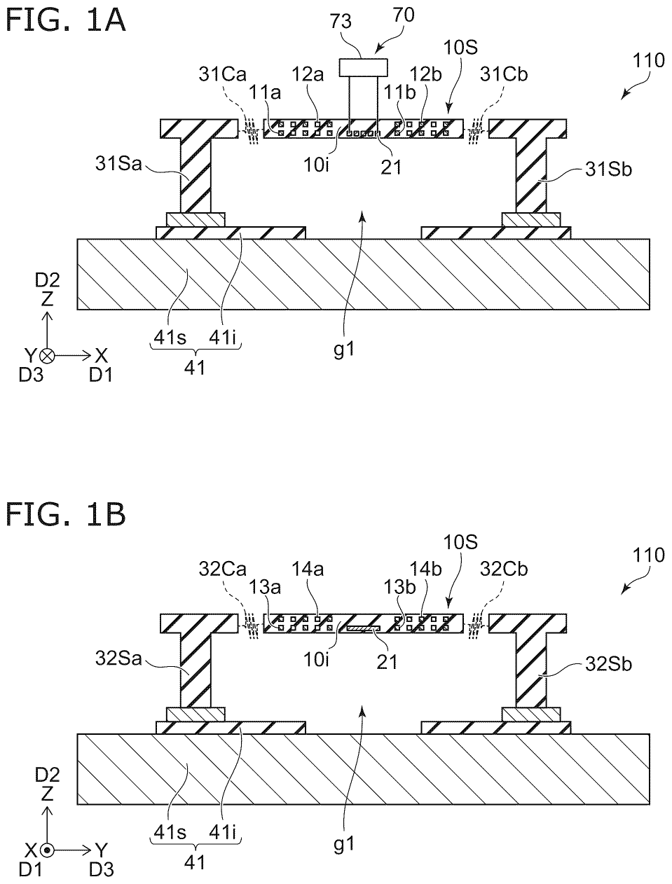

FIGS. 1A and 1B are schematic cross-sectional views illustrating a sensor according to the first embodiment.

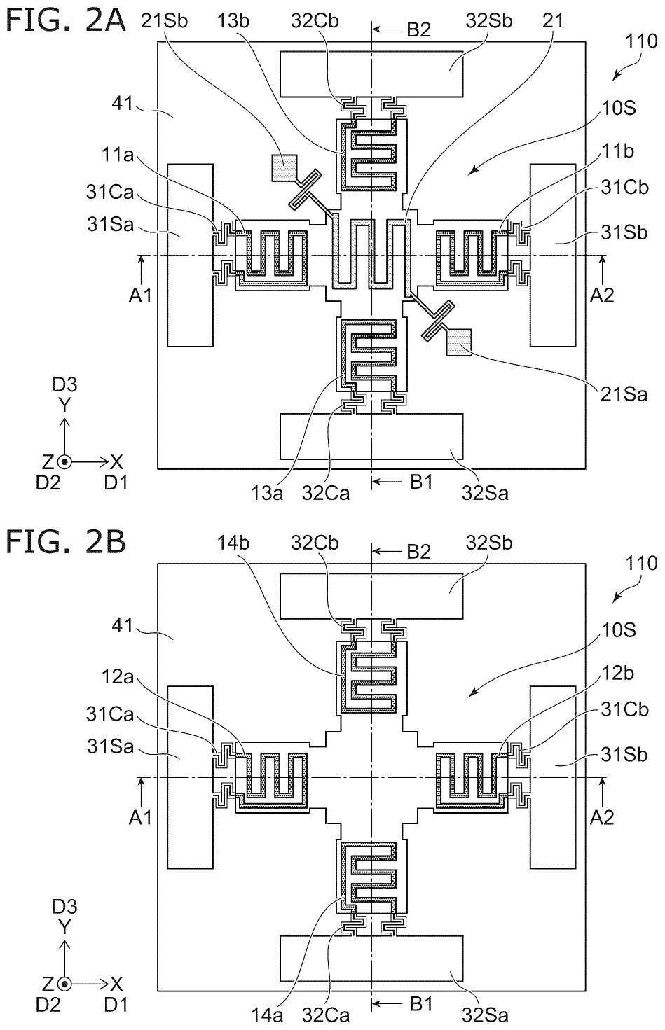

FIGS. 2A and 2B are schematic plan views illustrating the sensor according to the first embodiment.

FIG. 1A is a cross-sectional view taken along the line A1-A2 of FIGS. 2A and 2B. FIG. 1B is a cross-sectional view taken along the line B1-B2 of FIGS. 2A and 2B.

As shown in FIGS. 1A, 1B, 2A, and 2B, a sensor 110 according to the embodiment includes a sensor portion 10S. The sensor portion 10S includes a first resistance element 11a, a first opposing resistance element 11b, a second resistance element 12a, a second opposing resistance element 12b, a third resistance element 13a, a third opposing resistance element 13b, a fourth resistance element 14a, a fourth opposing resistance element 14b, and a first conductive member 21.

A direction from the first resistance element 11a to the first opposing resistance element 11b is along a first direction D1. The first direction D1 is defined as an X-axis direction. One direction perpendicular to the X-axis direction is defined as a Z-axis direction. A directions perpendicular to the X-axis direction and the Z-axis direction is defined as a Y-axis direction.

A second direction D2 from at least a part of the first resistance element 11a to the second resistance element 12a crosses the first direction D1. The second direction D2 may be the Z-axis direction, for example.

A direction from the second resistance element 12a to the second opposing resistance element 12b is along the first direction D1. A direction from at least a part of the first opposing resistance element 11b to the second opposing resistance element 12b is along the second direction.

A third direction D3 from the third resistance element 13a to the third opposing resistance element 13b crosses a plane including the first direction D1 and the second direction D2. The third direction D3 may be the Y-axis direction, for example.

A direction from at least a part of the third resistance element 13a to the fourth resistance element 14a is along the second direction D2.

A direction from the fourth resistance element 14a to the fourth opposing resistance element 14b is along the third direction D3. A direction from at least a part of the third opposing resistance element 13b to the fourth opposing resistance element 14b is along the second direction D2.

A position of the first conductive member 21 in the first direction D1 is between a position of the first resistance element 11a in the first direction D1 and a position of the first opposing resistance element 11b in the first direction D1. A position of the first conductive member 21 in the first direction D1 is between a position of the second resistance element 12a in the first direction D1 and a position of the second opposing resistance element 12b in the first direction D1.

FIG. 2A is a plan view in a plane including the first conductive member 21, the first resistance element 11a, the first opposing resistance element 11b, the third resistance element 13a and the third opposing resistance element 13b. FIG. 2B is a plan view in a plane including the second resistance element 12a, the second opposing resistance element 12b, the fourth resistance element 14a and the fourth opposing resistance element 14b.

A position of the first conductive member 21 in the third direction D3 is between a position of the third resistance element 13a in the third direction D3 and a position of the third opposing resistance element 13b in the third direction D3. A position of the first conductive member 21 in the third direction D3 is between a position of the fourth resistance element 14a in the third direction D3 and a position of the fourth opposing resistance element 14b in the third direction D3.

In this example, the first conductive member 21 is provided between the first resistance element 11a and the first opposing resistance element 11b in the first direction D1. The first conductive member 21 is provided between the third resistance element 13a and the third opposing resistance element 13b in the third direction D3.

The first conductive member 21 may be provided between the second resistance element 12a and the second opposing resistance element 12b in the first direction D1. The first conductive member 21 may be provided between the fourth resistance element 14a and the fourth opposing resistance element 14b in the third direction D3.

For example, at least a part of the first resistance element 11a overlaps the second resistance element 12a in the second direction D2. For example, at least a part of the first opposing resistance element 11b overlaps the second opposing resistance element 12b in the second direction D2. For example, at least a part of the third resistance element 13a overlaps the fourth resistance element 14a in the second direction D2. For example, at least a part of the third opposing resistance element 13b overlaps the fourth opposing resistance element 14b in the second direction D2.

In the embodiment, a current is supplied to the first conductive member 21 to increase the temperature of the first conductive member 21. The first conductive member 21 functions, for example, as a heater. For example, heat generated by the first conductive member 21 is transmitted to the first resistance element 11a, the first opposing resistance element 11b, the second resistance element 12a, the second opposing resistance element 12b, the third resistance element 13a, the third opposing resistance element 13b, the fourth resistance element 14a, and the fourth opposing resistance element 14b. The temperatures of the first resistance element 11a, the first opposing resistance element 11b, the second resistance element 12a, the second opposing resistance element 12b, the third resistance element 13a, the third opposing resistance element 13b, the fourth resistance element 14a and the fourth opposing resistance element 14b increase.

The electrical resistance of the resistance element changes with temperature. For example, a detection target substance (e.g., gas) flows from the first resistance element 11a toward the first opposing resistance element 11b. At this time, in the first resistance element 11a upstream of the gas flow, heat is taken away by the detection target substance and the temperature is lowered. On the other hand, the detection target substance heated by the first conductive member 21 passes through the first opposing resistance element 11b downstream of the gas flow. Therefore, the temperature of the first opposing resistance element 11b downstream increases. This causes a temperature difference between the first opposing resistance element 11b and the first resistance element 11a. The temperature difference can be detected as a difference in electrical resistance.

In the embodiment, one set of the first resistance element 11a and the first opposing resistance element 11b and another set of the second resistance element 12a and the second opposing resistance element 12b are provided in the first direction D1. By detecting the difference of the signals obtained from the one set, the flow rate of the detection target substance can be detected with high sensitivity.

In addition to the two sets of elements in the first direction D1, two other sets in the third direction D3 are provided. The two other sets in the third direction D3 are one set of the third resistance element 13a and the third opposing resistance element 13b and another set of the fourth resistance element 14a and the fourth opposing resistance element 14b. By processing the detection results obtained from the elements in these two directions, the direction of the flow of the detection target substance can be detected.

For example, a reference example in which the first resistance element 11a and the second resistance element 12a are not stacked and are arranged along the first direction D1 is considered. In this reference example, for example, the first opposing resistance element 11b and the second opposing resistance element 12b are not stacked and are arranged along the first direction D1. In this reference example, the distance between any of the plurality of resistance elements and the first conductive member 21 (heater) becomes long. Therefore, for example, the temperature of the detection target material whose temperature has increased passes through the position of the resistance element becomes low due to diffusion or the like. For example, in the resistance element having a long distance from the first conductive member 21 (heater), the temperature is hardly increased. Therefore, it is difficult to obtain high sensitivity. Furthermore, in this reference example, it is difficult to reduce the size of the sensor.

In contrast, in the embodiment, for example, the direction from the first resistance element 11a to the second resistance element 12a is the second direction D2 (Z-axis direction). That is, a plurality of resistance elements are stacked. With this configuration, the distance from the first conductive member 21 to the resistance element can be shortened. The detection target substance whose temperature is raised by the first conductive member 21 can pass through the position of the resistance element while maintaining its temperature. Thereby, high sensitivity can be obtained. A small sensor can be obtained. According to embodiments, a sensor capable of improving characteristics can be provided.

As shown in FIGS. 1A and 1B, for example, the sensor portion 10S includes an insulating member 10i. A part of the insulating member 10i is provided between the first resistance element 11a and the second resistance element 12a. A part of the insulating member 10i is provided between the first opposing resistance element 11b and the second opposing resistance element 12b. A part of the insulating member 10i is provided between the first resistance element 11a and the first conductive member 21. A part of the insulating member 10i is provided between the first opposing resistance element 11b and the first conductive member 21.

As shown in FIG. 1B, another part of the insulating member 10i is provided between the third resistance element 13a and the fourth resistance element 14a. Another part of the insulating member 10i is provided between the third opposing resistance element 13b and the fourth opposing resistance element 14b. Another part of the insulating member 10i is provided between the third resistance element 13a and the first conductive member 21. Another part of the insulating member 10i is provided between the third opposing resistance element 13b and the first conductive member 21.

The first resistance element 11a and the second resistance element 12a can be mutually replaced. The third resistance element 13a and the fourth resistance element 14a can be mutually replaced.

As shown in FIGS. 1A and 1B, the sensor 110 includes a base 41, a first support portion 31Sa, a first opposing support portion 31Sb, a second support portion 32Sa, and a second opposing support portion 32Sb. The base 41 includes, for example, a substrate 41s and an insulating film 41i. The substrate 41s may be, for example, a semiconductor substrate (for example, a silicon substrate). The insulating film 41i is provided on the substrate 41s. For example, the above support portions are provided on the insulating film 41i.

The first support portion 31Sa is fixed to base 41 and supports the sensor portion 10S. The first opposing support portion 31Sb is fixed to base 41 and supports the sensor portion 10S. The second support portion 32Sa is fixed to base 41 and supports the sensor portion 10S. The second opposing support portion 32Sb is fixed to base 41 and supports the sensor portion 10S. For example, the sensor portion 10S may be in a form of a membrane.

For example, a first gap g1 is provided between base 41 and the sensor portion 10S. By the first gap g1, in the sensor portion 10S, for example, the influence of temperature from the outside via base 41 is suppressed. Detection with higher accuracy becomes possible.

The sensor 110 may include a first connect portion 31Ca, a first opposing connect portion 31Cb, a second connect portion 32Ca, and a second opposing connect portion 32Cb. The first connect portion 31Ca is supported by the first support portion 31Sa to support the sensor portion 10S. The first opposing connect portion 31Cb is supported by the first opposing support portion 31Sb to support the sensor portion 10S. The second connect portion 32Ca is supported by the second support portion 32Sa to support the sensor portion 10S. The second opposing connect portion 32Cb is supported by the second opposing support portion 32Sb to support the sensor portion 10S.

A part of the first gap g1 is provided between base 41 and the first connect portion 31Ca, between base 41 and the first opposing connect portion 31Cb, between base 41 and the second connect portion 32Ca, and between base 41 and the second opposing connect portion 32Cb. The width of these connect portions is narrower than the width of the insulating member 10i. Thereby, conduction of the heat of the sensor portion 10S through these connect portions is suppressed. These connect portions may have, for example, a meander structure.

As shown in FIG. 2A, a part of the first conductive member 21 is supported by a conductive member support portion 21Sa. Another part of the first conductive member 21 is supported by a conductive member opposing support portion 21Sb. For example, a current for heating is supplied to the first conductive member 21 through the conductive member support portion 21Sa and the conductive member opposing support portion 21Sb.

As shown in FIG. 1A, the sensor 110 may include a circuit portion 70. The circuit portion 70 may be provided separately from the sensor 110. The circuit portion 70 includes, for example, a current circuit 73. The current circuit 73 is configured to heat the first conductive member 21 by supplying the current to the first conductive member 21. The circuit portion 70 may include a detection circuit as described below.

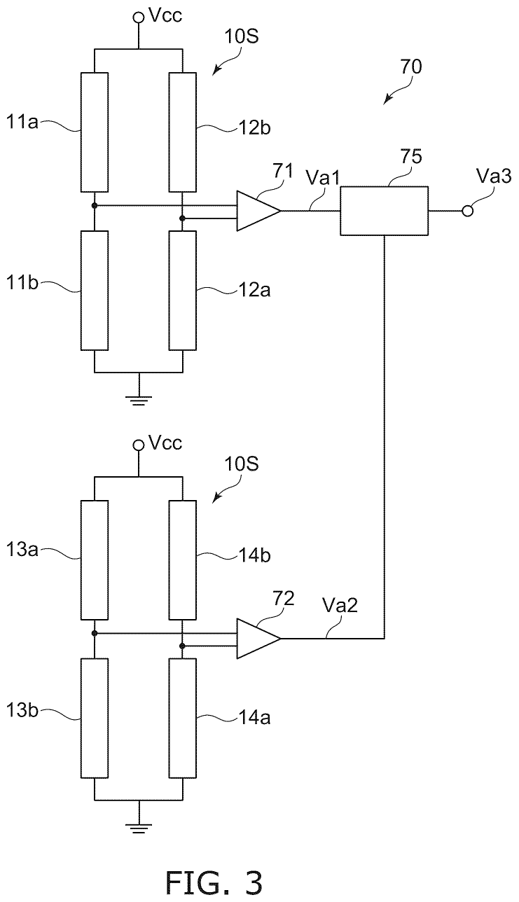

FIG. 3 is a circuit diagram illustrating a part of the sensor according to the first embodiment.

As shown in FIG. 3, the circuit portion 70 may include a first detection circuit 71 and a second detection circuit 72. For example, the first resistance element 11a, the first opposing resistance element 11b, the second resistance element 12a and the second opposing resistance element 12b form a Wheatstone bridge circuit. A voltage Vcc is applied to the Wheatstone bridge circuit.

The first detection circuit 71 is, for example, a differential circuit. The first detection circuit 71 detects, for example, a difference in potential between two midpoints of the Wheatstone bridge circuit. For example, the first detection circuit 71 is configured to output a first value Vat corresponding to a first difference between the first electric resistance of the first resistance element 11a and the first opposing electric resistance of the first opposing resistance element 11b, and a second difference between the second electric resistance of the second resistance element 12a and the second opposing electric resistance of the second opposing resistance element 12b. The first value Va1 corresponds to a flow rate along the first direction D1, for example.

For example, the third resistance element 13a, the third opposing resistance element 13b, the fourth resistance element 14a, and the fourth opposing resistance element 14b form another Wheatstone bridge circuit. The second detection circuit 72 is, for example, a differential circuit. The second detection circuit 72 detects, for example, a difference in potential between two midpoints of the Wheatstone bridge circuit. For example, the second detection circuit 72 is configured to output a second value Va2 corresponding to a third difference between the third electrical resistance of the third resistance element 13a and the third opposing electrical resistance of the third opposing resistance element 13b, and a fourth difference between the fourth electrical resistance of the fourth resistance element 14a and the fourth opposing electrical resistance of the fourth opposing resistance element 14b. The second value Va2 corresponds to a flow rate along the third direction D3, for example.

As shown in FIG. 3, the circuit portion 70 may further include a processing circuit 75. The processing circuit 75 is configured to output a third value Va3 based on the first value Va1 and the second value Va2. For example, the third value Va3 is a ratio of the first value Va1 to the second value Va2. The ratio of the first value Va1 to the second value Va2 corresponds to a tangent of a flow angle θ. Information on the flow direction (angle θ) is obtained from the first value Vat and the second value Va2.

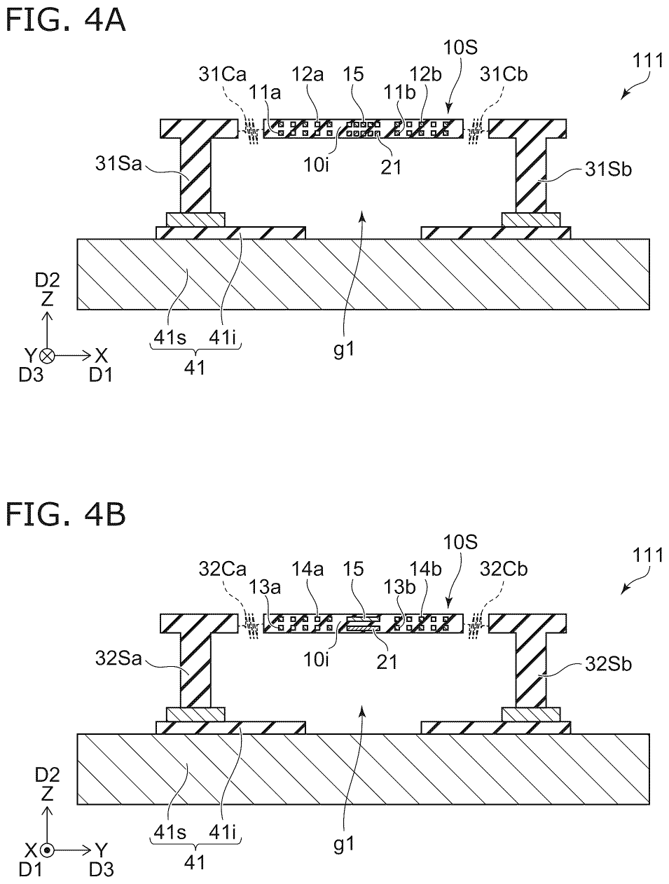

FIGS. 4A and 4B are schematic cross-sectional views illustrating a sensor according to the first embodiment.

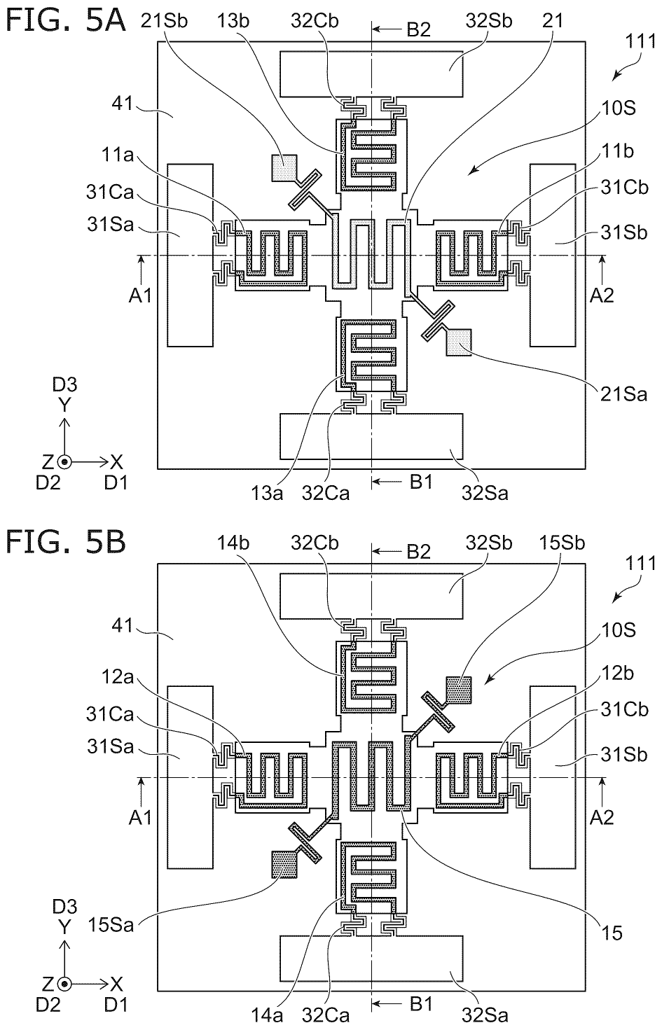

FIGS. 5A and 5B are schematic plan views illustrating the sensor according to the first embodiment.

FIG. 4A is a cross-sectional view taken along the line A1-A2 of FIGS. 5A and 5B. FIG. 4B is a cross-sectional view taken along the line B1-B2 of FIGS. 5A and 5B.

As shown in these figures, in a sensor 111 according to the embodiment, the sensor portion 10S includes the fifth resistance element 15. The configuration of the sensor 111 except for this may be the same as the configuration of the sensor 110.

As shown in FIGS. 4A and 4B, in a sensor 111, a direction from at least a part of the first conductive member 21 to the fifth resistance element 15 is along the second direction D2. For example, the fifth resistance element 15 overlaps the first conductive member 21 in the second direction D2.

For example, the current is supplied to the first conductive member 21 to raise the temperature of the first conductive member 21. Thereby, the temperature of the fifth resistance element 15 rises. The temperature of the fifth resistance element 15 changes according to the kind and concentration of the detection target substance (for example, a gas) existing around the fifth resistance element 15. This is based on a phenomena that the heat conduction characteristic (heat dissipation) changes according to the kind and concentration of the detection target substance (for example, a gas). The temperature change of the fifth resistance element 15 can be detected by detecting the resistance of the fifth resistance element 15. The concentration of the detection target substance can be detected from the detection result of the resistance change of the fifth resistance element 15.

FIG. 5B is a plan view of a plane including the fifth resistance element 15. As shown in FIG. 5B, a part of the fifth resistance element 15 is supported by the fifth support portion 15Sa. Another part of the fifth resistance element 15 is supported by the fifth opposing support portion 15Sb. For example, the electrical resistance of the fifth resistance element 15 may be detected through these support portions.

For example, the sensor 111 is configured to detect the flow rate, the flow direction, and the concentration of the detection target substance.

### Second Embodiment

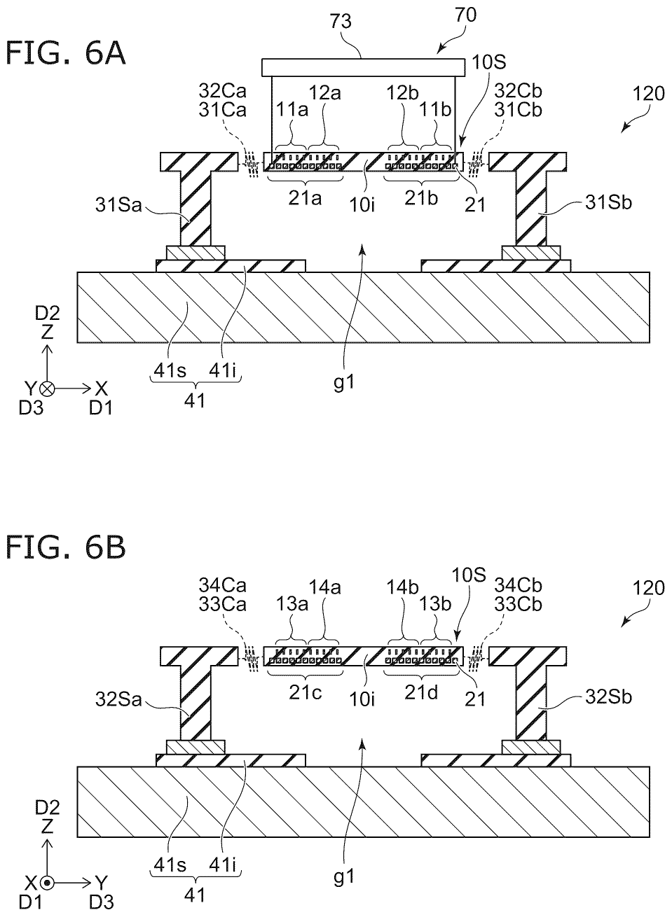

FIGS. 6A and 6B are schematic cross-sectional views illustrating a sensor according to a second embodiment.

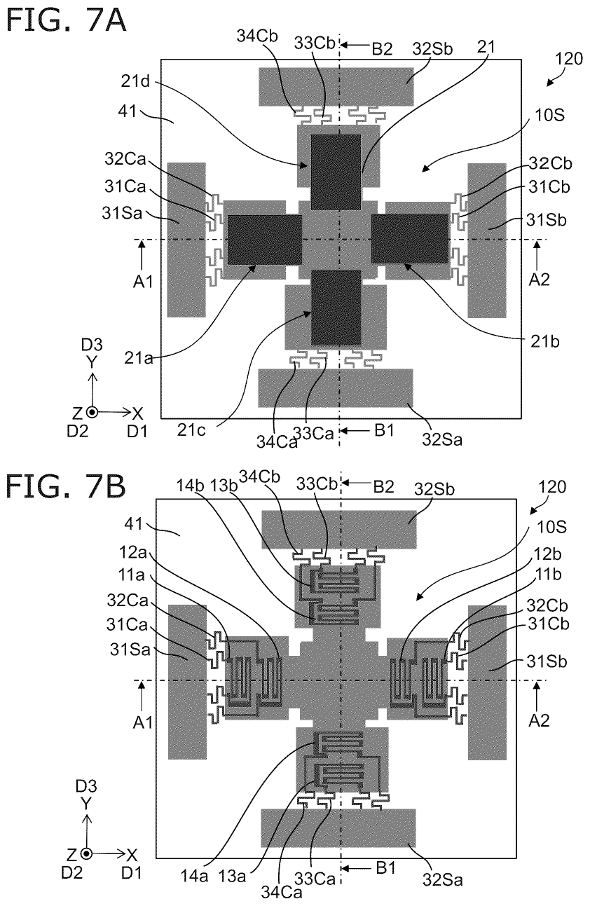

FIGS. 7A and 7B are schematic plan views illustrating the sensor according to the second embodiment.

FIG. 6A is a cross-sectional view taken along the line A1-A2 of FIGS. 7A and 7B. FIG. 6B is a cross-sectional view taken along the line B1-B2 of FIGS. 7A and 7B.

As shown in FIGS. 6A, 6B, 7A and 7B, a sensor 120 according to the embodiment includes the sensor portion 10S. The sensor portion 10S includes the first resistance element 11a, the first opposing resistance element 11b, the second resistance element 12a, the second opposing resistance element 12b, the third resistance element 13a, the third opposing resistance element 13b, the fourth resistance element 14a, the fourth opposing resistance element 14b, and the first conductive member 21.

The first conductive member 21 includes a first conductive portion 21a, a second conductive portion 21b, a third conductive portion 21c, and a fourth conductive portion 21d. These conductive portions are arranged along the X-Y plane. These conductive portions may be continuous with each other. For example, each of the first conductive portion 21a, the second conductive portion 21b, the third conductive portion 21c, and the fourth conductive portion 21d may have a meander structure. Thin wiring may be applied in the meander structure of each of these conductive portions. In the example of FIG. 7A, the meander structure is omitted for simplicity.

As shown in FIG. 6A, a direction from the first resistance element 11a to the second resistance element 12a is along the first direction D1. The first direction D1 is, for example, the X-axis direction. The second direction D2 from the first conductive portion 21a to the first resistance element 11a and the second resistance element 12a crosses the first direction D1. The second direction D2 may be in the Z-axis direction.

A direction from the first resistance element 11a to the first opposing resistance element 11b is along the first direction D1. The direction from the second resistance element 12a to the second opposing resistance element 12b is along the first direction D1. A direction from the second conductive portion 21b to the first opposing resistance element 11b and the second opposing resistance element 12b is along the second direction D2.

As shown in FIG. 7B, the third direction D3 from the third resistance element 13a to the fourth resistance element 14a crosses a plane including the first direction D1 and the second direction D2. The third direction D3 is, for example, in the Y-axis direction. A direction from the third conductive portion 21c to the third resistance element 13a and the fourth resistance element 14a is along the second direction D2.

A direction from the third resistance element 13a to the third opposing resistance element 13b is along the third direction D3. A direction from the fourth resistance element 14a to the fourth opposing resistance element 14b is along the third direction D3. A direction from the fourth conductive portion 21d to the third opposing resistance element 13b and the fourth opposing resistance element 14b is along the second direction D2.

In the sensor 120, for example, at least a part of the first conductive portion 21a overlaps the first resistance element 11a and the second resistance element 12a in the second direction D2 in the second direction D2. For example, at least a part of the second conductive portion 21b overlaps the first opposing resistance element 11b and the second opposing resistance element 12b. For example, at least a part of the third conductive portion 21c overlaps the third resistance element 13a and the fourth resistance element 14a in the second direction D2. At least a part of the fourth conductive portion 21d overlaps the third opposing resistance element 13b and the fourth opposing resistance element 14b.

In the sensor 120, the first conductive member 21 functioning as the heater overlaps the plurality of resistance elements. Thereby, the distance between the first conductive member 21 and the plurality of resistance elements can be shortened. Higher sensitivity can be obtained compared with a reference example in which the first conductive member 21 and the plurality of resistance elements do not overlap. For example, heating efficiency can be increased and power consumption can be reduced. According to sensor 120, a sensor capable of improving characteristics can be provided.

As shown in FIGS. 6A and 6B, the sensor portion 10S may include the insulating member 10i. At least a part of the insulating member 10i is provided between the first conductive portion 21a and the first resistance element 11a. At least a part of the insulating member 10i is provided between the first conductive portion 21a and the second resistance element 12a. At least a part of the insulating member 10i is provided between the second conductive portion 21b and the first opposing resistance element 11b. At least a part of the insulating member 10i is provided between the second conductive portion 21b and second opposing resistance element 12b. At least a part of the insulating member 10i is provided between the third conductive portion 21c and the third resistance element 13a. At least a part of the insulating member 10i is provided between the third conductive portion 21c and the fourth resistance element 14a. At least a part of the insulating member 10i is provided between the fourth conductive portion 21d and the third opposing resistance element 13b. At least a part of the insulating member 10i is provided between the fourth conductive portion 21d and the fourth opposing resistance element 14b.

As shown in FIGS. 6A and 6B, the sensor 120 includes the base 41, the first support portion 31Sa, the first opposing support portion 31Sb, the second support portion 32Sa, and the second opposing support portion 32Sb. The first support portion 31Sa is fixed to the base 41 and supports the sensor portion 10S. The first opposing support portion 31Sb is fixed to base 41 and supports the sensor portion 10S. The second support portion 32Sa is fixed to the base 41 and supports the sensor portion 10S. The second opposing support portion 32Sb is fixed to the base 41 and supports the sensor portion 10S. The first gap g1 is provided between the base 41 and the sensor portion 10S.

In the sensor 120, the circuit portion 70 described with respect to the sensor 110 may be provided. The circuit portion 70 may perform the operation described with respect to the sensor 110.

For example, as shown in FIG. 6A, the circuit portion 70 includes the current circuit 73. The current circuit 73 is configured to heat first conductive member 21 by supplying current to first conductive member 21.

The circuit portion 70 may include the first detection circuit 71 and the second detection circuit 72 (see FIG. 3). In the sensor 120, the first detection circuit 71 is configured to output the first value Va1 corresponding to the difference between first difference between the first electrical resistance of the first resistance element 11a and the first opposing electrical resistance of the first opposing resistance element 11b, and the second difference between the second electrical resistance of the second resistance element 12a and the second opposing electrical resistance of the second opposing resistance element 12b.

The second detection circuit 72 is configured to output the second value Va2 corresponding to the third difference between the third electrical resistance of the third resistance element 13a and the third opposing electrical resistance of the third opposing resistance element 13b, and the fourth difference between the fourth electrical resistance of the fourth resistance element 14a and the fourth electrical resistance of the fourth opposing resistance element 14b.

The circuit portion 70 may further include the processing circuit 75 (see FIG. 3). The processing circuit 75 is configured to output the third value Va3 based on the first value Vat and the second value Va2. For example, the third value Va3 is the ratio of the first value Va1 to the second value Va2. The ratio of the first value Va1 to the second value Va2 corresponds to the tangent of the flow angle θ. Information on the flow direction (angle θ) is obtained from the first value Vat and the second value Va2.

As shown in FIG. 7A, the first connect portion 31Ca, the first opposing connect portion 31Cb, the second connect portion 32Ca, and the second opposing connect portion 32Cb may be provided. These connect portions are fixed to base 41. These connect portions support the sensor portion 10S. These connecting portions may have, for example, a meander structure.

For example, the first resistance element 11a may be connected to the circuit portion 70 via the first connect portion 31Ca. For example, the first opposing resistance element 11b may be connected to the circuit portion 70 via the first opposing connect portion 31Cb. For example, the second resistance element 12a may be connected to the circuit portion 70 via the second connect portion 32Ca. For example, the second opposing resistance element 12b may be connected to the circuit portion 70 via the second opposing connect portion 32Cb.

For example, the third resistance element 13a may be connected to the circuit portion 70 via the third connect portion 33Ca. For example, the third opposing resistance element 13b may be connected to the circuit portion 70 via the third opposing connect portion 33Cb. For example, the fourth resistance element 14a may be connected to the circuit portion 70 via the fourth connect portion 34Ca. For example, the fourth opposing resistance element 14b may be connected to the circuit portion 70 via the fourth opposing connect portion 34Cb.

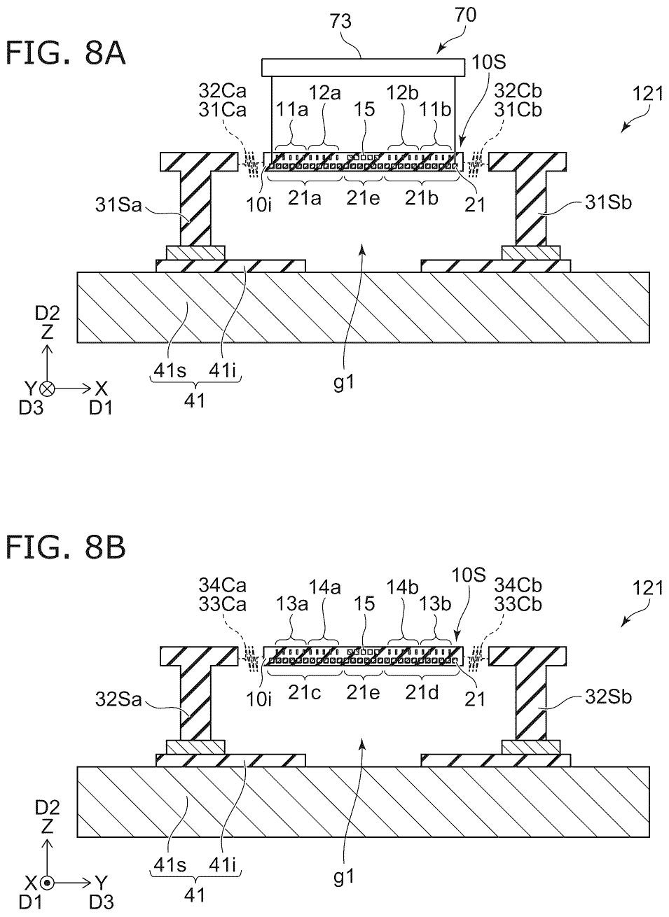

FIGS. 8A and 8B are schematic cross-sectional views illustrating a sensor according to the second embodiment.

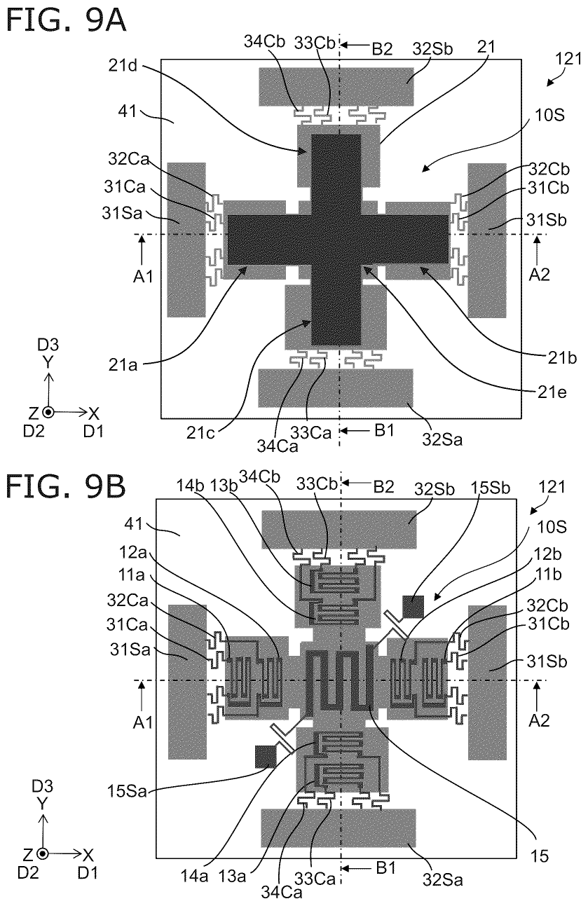

FIGS. 9A and 9B are schematic plan views illustrating the sensor according to the second embodiment.

FIG. 8A is a cross-sectional view taken along the line A1-A2 of FIGS. 9A and 9B. FIG. 8B is a cross-sectional view taken along the line B1-B2 of FIGS. 9A and 9B.

As shown in these figures, in a sensor 121 according to the embodiment, the sensor portion 10S includes the fifth resistance element 15. The configuration of the sensor 121 except for this may be the same as the configuration of the sensor 120.

As shown in FIGS. 8A and 8B, the first conductive member 21 may further include the fifth conductive portion 21e. The fifth conductive portion 21e may, for example, be continuous with another conductive portion (such as the first conductive portion 21a). A direction from the fifth conductive portion 21e to the fifth resistance element 15 is along the second direction D2. For example, the fifth resistance element 15 overlaps the fifth conductive portion 21e.

From the detection result of the change in resistance of the fifth resistance element 15, the type and concentration of the detection target substance can be detected. The sensor 121 is configured to detect, for example, the flow rate, the flow direction, and the type (or concentration) of the detection target substance.

In the sensor 121, the fifth conductive portion 21e is provided between the first conductive portion 21a and the second conductive portion 21b. The fifth conductive portion 21e is provided between the third conductive portion 21c and the fourth conductive portion 21d. As previously described, each of the plurality of conductive portions may have a meander structure. In the example of FIG. 9A, the meander structure is omitted for simplicity.

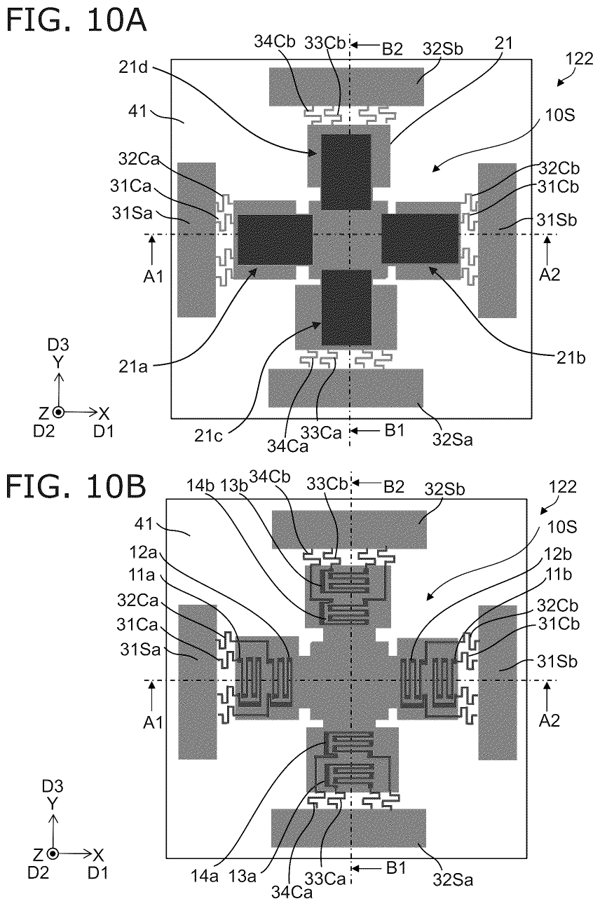

FIGS. 10A and 10B are schematic plan views illustrating a sensor according to the second embodiment.

As shown in FIGS. 10A and 10B, in the sensor 122 according to the embodiment, the configuration of the connect portion is different from the configuration of the connect portion in the sensor 121. Except for this, the configuration of the sensor 122 may be the same as the configuration of the sensor 120. In the embodiment, the configuration of the connect portions may be varied.

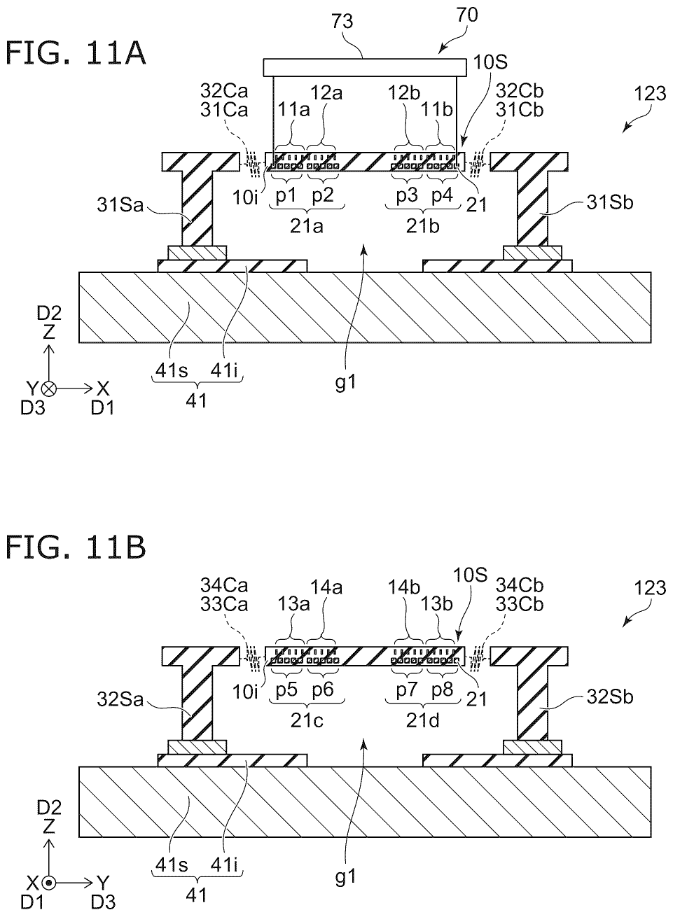

FIGS. 11A and 11B are schematic cross-sectional views illustrating a sensor according to the second embodiment.

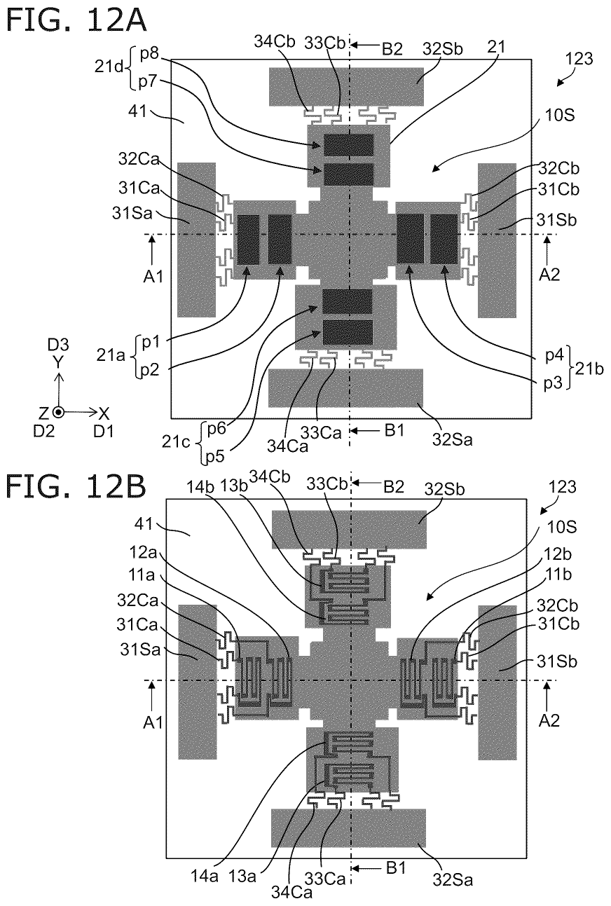

FIGS. 12A and 12B are schematic plan views illustrating the sensor according to the second embodiment.

FIG. 11A is a cross-sectional view taken along the line A1-A2 of FIGS. 12A and 12B. FIG. 11B is a cross-sectional view taken along the line B1-B2 of FIGS. 12A and 12B.

As shown in these figures, in a sensor 123 according to the embodiment, the first conductive member 21 included in the sensor portion 10S includes a first portion p1, a second portion p2, a third portion p3, a fourth portion p4, a fifth portion p5, a sixth portion p6, a seventh portion p7, and an eighth portion p8. These plurality of portions may have a meander structure. In the example of FIG. 12A, the meander structure is omitted for simplicity.

The plurality of portions may be independent of each other. Two or more portions included in the plurality of portions may be connected to each other.

For example, the first portion p1 and the second portion p2 may be included in the first conductive portion 21a. The third portion p3 and the fourth portion p4 may be included in the second conductive portion 21b. The fifth portion p5 and the sixth portion p6 may be included in the third conductive portion 21c. The seventh portion p7 and the eighth portion p8 may be included in the fourth conductive portion 21d.

High sensitivity is also obtained in the sensor 121, the sensor 122 and the sensor 123. For example, heating efficiency can be high, and power consumption can be reduced. According to these sensors, a sensor capable of improving characteristics can be provided.

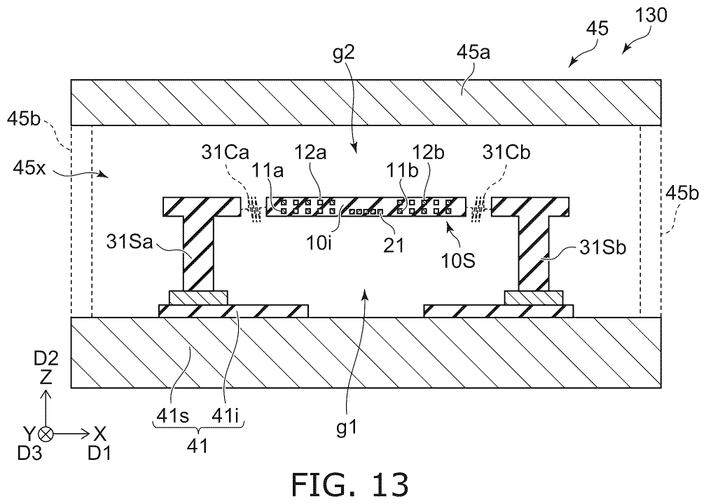

FIG. 13 is a schematic cross-sectional view illustrating a sensor according to an embodiment.

As shown in FIG. 13, a sensor 130 according to the embodiment includes a housing 45. The housing 45 includes, for example, a first housing portion 45a and a second housing portion 45b. The first housing portion 45a faces the sensor portion 10S in the second direction D2. The first housing portion 45a is, for example, a lid portion. The second housing portion 45b supports the first housing portion 45a so that a second gap g2 is provided between the sensor portion 10S and the first housing portion 45a. The second housing portion 45b is, for example, a column portion.

A plurality of second housing portions 45b may be provided discretely. A gap 45x exists between the plurality of second housing portions 45b. The detection target substance passes over the sensor portion 10S (second gap g2) through the gap 45x.

The embodiments may include the following Technical proposal:

### Technical Proposal 1

A sensor, comprising:
a sensor portion, the sensor portion including
   a first resistance element,
   a first opposing resistance element, a direction from the first resistance element to the first opposing resistance element being along a first direction,
   a second resistance element, a second direction from at least a part of the first resistance element to the second resistance element crossing the first direction,
   a second opposing resistance element, a direction from the second resistance element to the second opposing resistance element being along the first direction, a direction from at least a part of the first opposing resistance element to the second opposing resistance element being along the second direction,
   a third resistance element,
   a third opposing resistance element, a third direction from the third resistance element to the third opposing resistance element crossing a plane including the first direction and the second direction,
   a fourth resistance element, a direction from at least a part of the third resistance element to the fourth resistance element being along the second direction,
   a fourth opposing resistance element, a direction from the fourth resistance element to the fourth opposing resistance element being along the third direction, a direction from at least a part of the third opposing resistance element to the fourth opposing resistance element being along the second direction, and
   a first conductive member, a position of the first conductive member in the first direction being between a position of the first resistance element in the first direction and a position of the first opposing resistance element in the first direction, a position of the first conductive member in the third direction being between a position of the third resistance element in the third direction and a position of the third opposing resistance element in the third direction.

### Technical Proposal 2

The sensor according to Technical proposal 1, wherein
the first conductive member is provided between the first resistance element and the first opposing resistance element in the first direction, and
the first conductive member is provided between the third resistance element and the third opposing resistance element in the third direction.

### Technical Proposal 3

The sensor according to Technical proposal 1 or 2, further comprising:
an insulating member,
a part of the insulating member being provided between the first resistance element and the second resistance element, between the first opposing resistance element and the second opposing resistance element, between the first resistance element and the first conductive member, and between the first opposing resistance element and the first conductive member.

### Technical Proposal 4

The sensor according to Technical proposal 3, wherein
another part of the insulating member is provided between the third resistance element and the fourth resistance element, between the third opposing resistance element and the fourth opposing resistance element, between the third resistance element and the first conductive member, and between the third opposing resistance element and the first conductive member.

### Technical Proposal 5

The sensor according to any one of Technical proposals 1-4, further comprising:
a base;
a first support portion fixed to base and supporting the sensor portion;
a first opposing support portion fixed to base and supporting the sensor portion;
a second support portion fixed to base and supporting the sensor portion; and
a second opposing support portion fixed to base and supporting the sensor portion, and
a first gap being provided between the base and the portion.

### Technical Proposal 6

The sensor according to Technical proposal 5, further comprising:
a first connect portion being supported by the first support portion and supporting the sensor portion;
a first opposing connect being supported by the first opposing support portion and supporting the sensor portion;
a second connect portion being supported by the second support portion and supporting the sensor portion; and
a second opposing connect portion being supported by the second opposing support portion and supporting the sensor portion,
a part of the first gap being provided between base and the first connect portion, between base and the first opposing connect portion, between base and the second connect portion, and between base and the second opposing connect portion.

### Technical Proposal 7

The sensor according to any one of Technical proposals 1-6, further comprising:
a circuit portion,
the circuit portion including a first detection circuit, a second detection circuit, and a current circuit,
the current circuit being configured to supply a current to the first conductive member to heat the first conductive member,
the first detection circuit being configured to output a first value corresponding to a difference between a first difference between a first electrical resistance of the first resistance element and a first opposing electrical resistance of the first opposing resistance element, and a second difference between a second electrical resistance of the second resistance element and a second opposing electrical resistance of the second opposing resistance element, and
the second detection circuit being configured to output a second value corresponding to a difference between a third difference between a third electrical resistance of the third resistance element and a third opposing resistance of the third opposing resistance element, and a fourth difference between a fourth electrical resistance of the fourth resistance element and a fourth opposing resistance of the fourth opposing resistance element.

### Technical Proposal 8

The sensor according to Technical proposal 7, wherein
the circuit portion further includes a processing circuit, and
the processing circuit is configured to output a third value based on the first value and the second value.

### Technical Proposal 9

The sensor according to any one of Technical proposals 1-8, wherein
the sensor portion further includes a fifth resistance element, and
a direction from at least a part of the first conductive member to the fifth resistance element is along the second direction.

### Technical Proposal 10

The sensor according to any one of Technical proposals 1-9, wherein
at least a part of the first resistance element overlaps the second resistance element in the second direction,
at least a part of the first opposing resistance element overlaps the second opposing resistance element in the second direction,
at least a part of the third resistance element overlaps the fourth resistance element in the second direction, and
at least a part of the third opposing resistance element overlaps the fourth opposing resistance element in the second direction.

### Technical Proposal 11

A sensor, comprising:
a sensor portion, the sensor portion including
   a first conductive member including a first conductive portion, a second conductive portion, a third conductive portion, and a fourth conductive portion,
   a first resistance element,
   a second resistance element, a direction from the first resistance element to the second resistance element being along a first direction, a second direction from the first conductive portion to the first resistance element and the second resistance element crossing the first direction,
   a first opposing resistance element, a direction from the first resistance element to the first opposing resistance element being along the first direction,
   a second opposing resistance element, a direction from the second resistance element to the second opposing resistance element being along the first direction, a direction from the second conductive portion to the first opposing resistance element and the second opposing resistance element being along the second direction,
   a third resistance element,
   a fourth resistance element, a third direction from the third resistance element to the fourth resistance element crossing a plane including the first direction and the second direction, a direction from the third conductive portion to the third resistance element and the fourth resistance element being along the second direction,
   a third opposing resistance element, a direction from the third resistance element to the third opposing resistance element being along the third direction,
   a fourth opposing resistance element, a direction from the fourth resistance element to the fourth opposing resistance element being along the third direction, a direction from the fourth conductive portion to the third opposing resistance element and the fourth opposing resistance element being along the second direction.

### Technical Proposal 12

The sensor according to Technical proposal 11, wherein
the sensor portion further includes an insulating member,
at least a part of the insulating member is provided
   between the first conductive portion and the first resistance element,
   between the first conductive portion and the second resistance element,
   between the second conductive portion and the first opposing resistance element,
   between the second conductive portion and the second opposing resistance element,
   between the third conductive portion and the third resistance element, and
   between the third conductive portion and the fourth resistance element,
   between the fourth conductive portion and the third opposing resistance element, and
   between the fourth conductive portion and the fourth opposing resistance element.

### Technical Proposal 13

The sensor according to Technical proposal 11 or 12, further comprising:
a base;
a first support portion being fixed to base and supporting the sensor portion;
a first opposing support portion being fixed to base and supporting the sensor portion;
a second support portion being fixed to base and supporting the sensor portion; and
a second opposing support portion being fixed to base and supporting the sensor portion, and
a first gap being provided between base and the sensor portion.

### Technical Proposal 14

The sensor according to any one of Technical proposals 11-13, further comprising:
a circuit portion including a first detection circuit, a second detection circuit, and a current circuit,
the current circuit being configured to supply a current to the first conductive member to heat the first conductive member,
the first detection circuit being configured to output a first value corresponding to a difference between a first difference between a first electrical resistance of the first resistance element and a first opposing electrical resistance of the first opposing resistance element, and a second difference between a second electrical resistance of the second resistance element and a second opposing electrical resistance of the second opposing resistance element, and
the second detection circuit being configured to output a second value corresponding to a difference between a third difference between a third electrical resistance of the third resistance element and a third opposing resistance of the third opposing resistance element, and a fourth difference between a fourth electrical resistance of the fourth resistance element and a fourth opposing resistance of the fourth opposing resistance element.

### Technical Proposal 15

The sensor according to Technical proposal 14, wherein
the circuit portion further includes a processing circuit, and
the processing circuit is configured to output a third value based on the first value and the second value.

### Technical Proposal 16

The sensor according to any one of Technical proposals 11-15, wherein
the sensor portion further includes a fifth resistance element,
the first conductive member further includes a fifth conductive portion, and
a direction from the fifth conductive portion to the fifth resistance element is along the second direction.

### Technical Proposal 17

The sensor according to any one of Technical proposals 11-16, wherein
at least a part of the first conductive portion overlaps the first resistance element in the second direction.

### Technical Proposal 18

The sensor according to any one of Technical proposals 1-17, further comprising:
a housing including a first housing portion and a second housing portion,
the first housing portion facing the sensor portion in the second direction, and
the second housing portion supporting the first housing portion to make a second gap being provided between the sensor portion and the first housing portion.

### Technical Proposal 19

A sensor, comprising:
a sensor portion including
   a first resistance element,
   a first opposing resistance element, a direction from the first resistance element to the first opposing resistance element being along a first direction,
   a second resistance element, a second direction from at least a part of the first resistance element to the second resistance element crossing the first direction,
   a second opposing resistance element, a direction from the second resistance element to the second opposing resistance element being along the first direction, a direction from at least a part of the first opposing resistance element to the second opposing resistance element being along the second direction,
   a first conductive member, a position of the first conductive member in the first direction being between a position of the first resistance element in the first direction and a position of the first opposing resistance element in the first direction.

### Technical Proposal 20

A sensor, comprising:
a sensor portion including
   a first conductive member including a first conductive portion and a second conductive portion,
   a first resistance element,
   a second resistance element, a direction from the first resistance element to the second resistance element being along a first direction, a second direction from the first conductive portion to the first resistance element and the second resistance element crossing the first direction,
   a first opposing resistance element, a direction from the first resistance element to the first opposing resistance element being along the first direction, and
   a second opposing resistance element, a direction from the second resistance element to the second opposing resistance element being along the first direction, a direction from the second conductive portion to the first opposing resistance element and the second opposing resistance element being along the second direction.

According to an embodiment, a sensor capable of improving characteristics can be provided.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the sensors such as bases, controllers, circuit portions, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all sensors practicable by an appropriate design modification by one skilled in the art based on the sensors described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A sensor, comprising:
a sensor portion, the sensor portion including
a first resistance element,
a first opposing resistance element, a direction from the first resistance element to the first opposing resistance element being along a first direction,
a second resistance element, a second direction from at least a part of the first resistance element to the second resistance element crossing the first direction,
a second opposing resistance element, a direction from the second resistance element to the second opposing resistance element being along the first direction, a direction from at least a part of the first opposing resistance element to the second opposing resistance element being along the second direction,
a third resistance element,
a third opposing resistance element, a third direction from the third resistance element to the third opposing resistance element crossing a plane including the first direction and the second direction,
a fourth resistance element, a direction from at least a part of the third resistance element to the fourth resistance element being along the second direction,
a fourth opposing resistance element, a direction from the fourth resistance element to the fourth opposing resistance element being along the third direction, a direction from at least a part of the third opposing resistance element to the fourth opposing resistance element being along the second direction, and
a first conductive member, a position of the first conductive member in the first direction being between a position of the first resistance element in the first direction and a position of the first opposing resistance element in the first direction, a position of the first conductive member in the third direction being between a position of the third resistance element in the third direction and a position of the third opposing resistance element in the third direction.

2. The sensor according to claim 1, wherein
the first conductive member is provided between the first resistance element and the first opposing resistance element in the first direction, and
the first conductive member is provided between the third resistance element and the third opposing resistance element in the third direction.

3. The sensor according to claim 1, further comprising:
an insulating member,
a part of the insulating member being provided between the first resistance element and the second resistance element, between the first opposing resistance element and the second opposing resistance element, between the first resistance element and the first conductive member, and between the first opposing resistance element and the first conductive member.

4. The sensor according to claim 3, wherein
another part of the insulating member is provided between the third resistance element and the fourth resistance element, between the third opposing resistance element and the fourth opposing resistance element, between the third resistance element and the first conductive member, and between the third opposing resistance element and the first conductive member.

5. The sensor according to claim 1, further comprising:
a base;
a first support portion fixed to base and supporting the sensor portion;
a first opposing support portion fixed to base and supporting the sensor portion;
a second support portion fixed to base and supporting the sensor portion; and
a second opposing support portion fixed to base and supporting the sensor portion, and
a first gap being provided between the base and the portion.

6. The sensor according to claim 5, further comprising:
a first connect portion being supported by the first support portion and supporting the sensor portion;
a first opposing connect being supported by the first opposing support portion and supporting the sensor portion;
a second connect portion being supported by the second support portion and supporting the sensor portion; and
a second opposing connect portion being supported by the second opposing support portion and supporting the sensor portion,
a part of the first gap being provided between base and the first connect portion, between base and the first opposing connect portion, between base and the second connect portion, and between base and the second opposing connect portion.

7. The sensor according to claim 1, further comprising:
a circuit portion,
the circuit portion including a first detection circuit, a second detection circuit, and a current circuit,
the current circuit being configured to supply a current to the first conductive member to heat the first conductive member,
the first detection circuit being configured to output a first value corresponding to a difference between a first difference between a first electrical resistance of the first resistance element and a first opposing electrical resistance of the first opposing resistance element, and a second difference between a second electrical resistance of the second resistance element and a second opposing electrical resistance of the second opposing resistance element, and
the second detection circuit being configured to output a second value corresponding to a difference between a third difference between a third electrical resistance of the third resistance element and a third opposing resistance of the third opposing resistance element, and a fourth difference between a fourth electrical resistance of the fourth resistance element and a fourth opposing resistance of the fourth opposing resistance element.

8. The sensor according to claim 7, wherein
the circuit portion further includes a processing circuit, and
the processing circuit is configured to output a third value based on the first value and the second value.

9. The sensor according to claim 1, wherein
the sensor portion further includes a fifth resistance element, and
a direction from at least a part of the first conductive member to the fifth resistance element is along the second direction.

10. The sensor according to claim 1, wherein
at least a part of the first resistance element overlaps the second resistance element in the second direction,
at least a part of the first opposing resistance element overlaps the second opposing resistance element in the second direction,
at least a part of the third resistance element overlaps the fourth resistance element in the second direction, and
at least a part of the third opposing resistance element overlaps the fourth opposing resistance element in the second direction.

11. A sensor, comprising:
a sensor portion, the sensor portion including
a first conductive member including a first conductive portion, a second conductive portion, a third conductive portion, and a fourth conductive portion,
a first resistance element,
a second resistance element, a direction from the first resistance element to the second resistance element being along a first direction, a second direction from the first conductive portion to the first resistance element and the second resistance element crossing the first direction,
a first opposing resistance element, a direction from the first resistance element to the first opposing resistance element being along the first direction,
a second opposing resistance element, a direction from the second resistance element to the second opposing resistance element being along the first direction, a direction from the second conductive portion to the first opposing resistance element and the second opposing resistance element being along the second direction,
a third resistance element,
a fourth resistance element, a third direction from the third resistance element to the fourth resistance element crossing a plane including the first direction and the second direction, a direction from the third conductive portion to the third resistance element and the fourth resistance element being along the second direction,
a third opposing resistance element, a direction from the third resistance element to the third opposing resistance element being along the third direction,
a fourth opposing resistance element, a direction from the fourth resistance element to the fourth opposing resistance element being along the third direction, a direction from the fourth conductive portion to the third opposing resistance element and the fourth opposing resistance element being along the second direction.

12. The sensor according to claim 11, wherein
the sensor portion further includes an insulating member,
at least a part of the insulating member is provided
between the first conductive portion and the first resistance element,
between the first conductive portion and the second resistance element,
between the second conductive portion and the first opposing resistance element,
between the second conductive portion and the second opposing resistance element,
between the third conductive portion and the third resistance element, and
between the third conductive portion and the fourth resistance element,
between the fourth conductive portion and the third opposing resistance element, and
between the fourth conductive portion and the fourth opposing resistance element.

13. The sensor according to claim 11, further comprising:
a base;
a first support portion being fixed to base and supporting the sensor portion;
a first opposing support portion being fixed to base and supporting the sensor portion;
a second support portion being fixed to base and supporting the sensor portion; and
a second opposing support portion being fixed to base and supporting the sensor portion, and
a first gap being provided between base and the sensor portion.

14. The sensor according to claim 11, further comprising:
a circuit portion including a first detection circuit, a second detection circuit, and a current circuit,
the current circuit being configured to supply a current to the first conductive member to heat the first conductive member,
the first detection circuit being configured to output a first value corresponding to a difference between a first difference between a first electrical resistance of the first resistance element and a first opposing electrical resistance of the first opposing resistance element, and a second difference between a second electrical resistance of the second resistance element and a second opposing electrical resistance of the second opposing resistance element, and
the second detection circuit being configured to output a second value corresponding to a difference between a third difference between a third electrical resistance of the third resistance element and a third opposing resistance of the third opposing resistance element, and a fourth difference between a fourth electrical resistance of the fourth resistance element and a fourth opposing resistance of the fourth opposing resistance element.

15. The sensor according to claim 14, wherein
the circuit portion further includes a processing circuit, and
the processing circuit is configured to output a third value based on the first value and the second value.

16. The sensor according to claim 11, wherein
the sensor portion further includes a fifth resistance element,
the first conductive member further includes a fifth conductive portion, and
a direction from the fifth conductive portion to the fifth resistance element is along the second direction.

17. The sensor according to claim 11, wherein
at least a part of the first conductive portion overlaps the first resistance element in the second direction.

18. The sensor according to claim 1, further comprising:
a housing including a first housing portion and a second housing portion,
the first housing portion facing the sensor portion in the second direction, and
the second housing portion supporting the first housing portion to make a second gap being provided between the sensor portion and the first housing portion.

19. A sensor, comprising:
a sensor portion including
a first resistance element,
a first opposing resistance element, a direction from the first resistance element to the first opposing resistance element being along a first direction,
a second resistance element, a second direction from at least a part of the first resistance element to the second resistance element crossing the first direction,
a second opposing resistance element, a direction from the second resistance element to the second opposing resistance element being along the first direction, a direction from at least a part of the first opposing resistance element to the second opposing resistance element being along the second direction,
a first conductive member, a position of the first conductive member in the first direction being between a position of the first resistance element in the first direction and a position of the first opposing resistance element in the first direction.

20. A sensor, comprising:
a sensor portion including
a first conductive member including a first conductive portion and a second conductive portion,
a first resistance element,
a second resistance element, a direction from the first resistance element to the second resistance element being along a first direction, a second direction from the first conductive portion to the first resistance element and the second resistance element crossing the first direction,
a first opposing resistance element, a direction from the first resistance element to the first opposing resistance element being along the first direction, and
a second opposing resistance element, a direction from the second resistance element to the second opposing resistance element being along the first direction, a direction from the second conductive portion to the first opposing resistance element and the second opposing resistance element being along the second direction.
